(19) United States
(12) Patent Application Publication
(10) Pub. No.: US 2025/0311125 A1
(43) Pub. Date: Oct. 2, 2025

(54) DISPLAY ASSEMBLY AND ELECTRONIC DEVICE

(71) Applicant: Lenovo (Beijing) Limited, Beijing (CN)

(72) Inventors: Shaopeng PENG, Beijing (CN); Chenglun ZHENG, Beijing (CN)

(21) Appl. No.: 19/078,382

(22) Filed: Mar. 13, 2025

(30) Foreign Application Priority Data
Mar. 26, 2024 (CN) 202410353926.2

(51) Int. Cl. H05K 5/02

(52) U.S. Cl. CPC H05K 5/0217

(57) ABSTRACT

A display assembly includes a first functional layer and a second functional layer. The first functional layer is configured for display and includes a bendable area. The second functional layer is configured to provide support to the first functional layer. The second functional layer includes a first support area and a second support area, and the second support area corresponds to the bendable area. The first support area includes a first surface and a second surface opposite to each other, with the first surface close to the first functional layer, and the second support area includes a third surface and a fourth surface opposite to each other, with the third surface close to the first functional layer. The third surface and the fourth surface are independent from each other, and the second support area does not have a structure penetrating the third surface and the fourth surface.

### CROSS-REFERENCE TO RELATED APPLICATION

The present disclosure claims priority to Chinese Patent Application No. 202410353926.2, filed on Mar. 26, 2024, the entire content of which is incorporated herein by reference.

### TECHNICAL FIELD

The present disclosure is related to the electronic device technology field and, more particularly, to a display assembly.

### BACKGROUND

A bendable electronic device includes a bendable display member and a support member for supporting the display member. The support member provides support to the display member and needs to deform with the bending of the display member.

A bending area of the support member generally includes a gap formed by etching to match the bending deformation of the electronic device. However, a foreign object may enter the gap to affect the display member and even cause damage to the display member.

### SUMMARY

An aspect of the present disclosure provides a display assembly including a first functional layer and a second functional layer. The first functional layer is configured for display and includes a bendable area. The second functional layer is configured to support the first functional layer. The second functional layer includes a first support area and a second support area, and the second support area corresponds to the bendable area. The first support area includes a first surface and a second surface opposite to each other, with the first surface close to the first functional layer, and the second support area includes a third surface and a fourth surface opposite to each other, with the third surface close to the first functional layer. The third surface and the fourth surface are independent of each other, and the second support area does not have a structure penetrating the third surface and the fourth surface. Under a unit area, an amount of solid material between the third surface and the fourth surface is less than an amount of solid material between the first surface and the second surface.

An aspect of the present disclosure provides an electronic device, including a bendable body and a display assembly. The first functional layer is configured for display and includes a bendable area. The second functional layer is connected to the body and configured to support the first functional layer. The second functional layer includes a first support area and a second support area, and the second support area corresponds to the bendable area. The first support area includes a first surface and a second surface opposite to each other, with the first surface close to the first functional layer, and the second support area includes a third surface and a fourth surface opposite to each other, with the third surface close to the first functional layer. The third surface and the fourth surface are independent of each other, and the second support area does not have a structure penetrating the third surface and the fourth surface. Under a unit area, an amount of solid material between the third surface and the fourth surface is less than an amount of solid material between the first surface and the second surface. The bendable area of the first functional layer corresponds to the bendable area of the body.

### BRIEF DESCRIPTION OF THE DRAWINGS

FIG. 1 is a schematic structural diagram of a display assembly according to some embodiments of the present disclosure.

FIG. 2 is a schematic diagram showing a first cross-section of a display assembly according to some embodiments of the present disclosure.

FIG. 3 is a schematic diagram showing a second cross-section of a display assembly according to some embodiments of the present disclosure.

FIG. 4 is a schematic diagram showing a third cross-section of a display assembly according to some embodiments of the present disclosure.

FIG. 5 is a schematic cross-section diagram of a first support layer according to some embodiments of the present disclosure.

FIG. 6 is a schematic diagram showing a fourth cross-section of a display assembly according to some embodiments of the present disclosure.

FIG. 7 is a schematic diagram showing a fifth cross-section of a display assembly according to some embodiments of the present disclosure.

FIG. 8 is a schematic diagram showing a sixth cross-section of a display assembly according to some embodiments of the present disclosure.

### DETAILED DESCRIPTION OF THE EMBODIMENTS

The present disclosure provides a display assembly and an electronic device.

The technical solutions of embodiments of the present disclosure are described in detail in conjunction with the accompanying drawings of embodiments of the present disclosure. Obviously, the described embodiments are only some embodiments of the present disclosure, not all embodiments of the present disclosure. Based on embodiments of the present disclosure, all other embodiments obtained by those of ordinary skill in the art without creative efforts shall fall within the scope of the present disclosure.

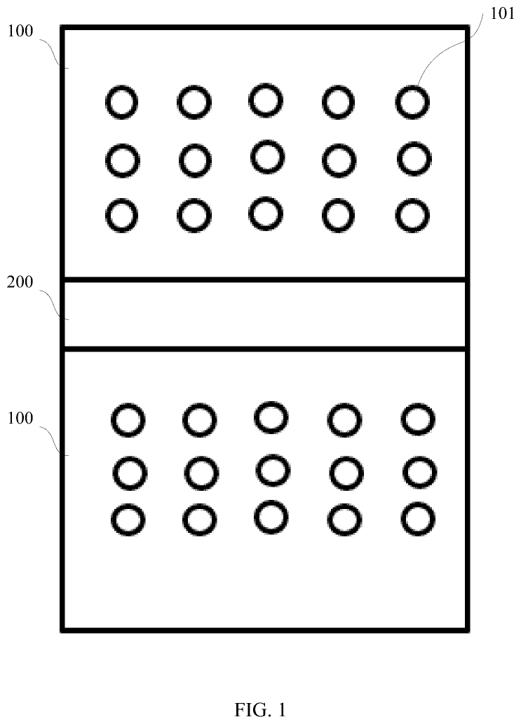

FIG. 1 is a schematic structural diagram of a display assembly according to some embodiments of the present disclosure. The display assembly includes a first functional layer and a second functional layer.

The first functional layer can be configured for display and include a bendable area.

The first functional layer can be a flexible screen or a light board with a bendable area. The bendable area can be an area of the first functional layer, while other areas of the first functional layer can be non-bendable. In some other embodiments, the entire first functional layer can be bendable (e.g., the first functional layer is a flexible screen). When the first functional layer cooperates with another member (e.g., the second functional layer or the housing of the electronic device), the first functional layer can include a bendable area, while other areas of the first functional layer (not overlapping with the bendable area) may not be bendable with the restriction of the another member (the second functional layer or the housing of the electronic device).

The second functional layer can be configured to support the first functional layer.

The second functional layer can support and protect the first functional layer to ensure the effective implementation of the first functional layer. For example, an external force can be directly applied to the first functional layer. Since the second functional layer provides support to the first functional layer, the first functional layer can be prevented from sinking toward the second functional layer to partially deform. Thus, the display effect of the first functional layer can be ensured. In some embodiments, the first functional layer can be a touch screen. When a human hand or an operation member (e.g., a stylus) can contact the first functional layer to apply pressure to the first functional layer. Since the second functional layer provides support to the first functional layer, the area of the first functional layer where the pressure is applied can be prevented from deforming relative to the surrounding area. Thus, the second functional layer can provide support to the first functional layer no matter whether the bendable area of the first functional layer is in the bent state or unbent state.

The second functional layer includes a first support area 100 and a second support area 200. The second support area 200 corresponds to the bendable area. The first support area 100 can be relatively independent of the second support area 200. In some embodiments, the first support area 100 can correspond to another area of the first functional layer (not overlapping with the bendable area).

The first support area 100 can include a first surface and a second surface opposite to each other. The first surface is close to the first functional layer. The second support area 200 can include a third surface and a fourth surface opposite to each other. The third surface is close to the first functional layer.

The third surface and the fourth surface can be relatively independent. The second support area 200 may not include a structure that penetrates through the third surface and the fourth surface. Through this arrangement, solid substances (foreign objects, such as dust or other particles) on both sides of the second support area 200 (the side facing the third surface and the side facing the fourth surface) cannot pass through the second support area 200.

Moreover, under a unit area, the amount of solid material between the third surface and the fourth surface can be less than the amount of solid material between the first surface and the second surface. The unit area can refer to the area on the first surface, second surface, third surface, and fourth surface. With the amount of solid material between the third surface and the fourth surface being less than the amount of solid material between the first surface and the second surface, when subjected to a bending force, the bending deformation of the second support area 200 can be greater than the bending deformation of the first support area 100. Thus, the second support area 200 can provide effective support to the bendable area.

In the display assembly of embodiments of the present disclosure, in the bent state and the unbent state of the bendable area of the first functional layer, the second functional layer can provide support to the first functional layer. Moreover, the external foreign objects cannot penetrate the second functional layer to contact the first functional layer to reduce the negative impact on the display member.

The display assembly can include a first end and a second end opposite to each other. When the bendable area of the first functional layer is in the bent state, the first end and the second end can be relatively closer. In some embodiments, the side surface of the first functional layer and the side surface of the second functional layer can correspond to the side surfaces of the display assembly. The side surfaces of the display assembly can be arranged between the first end and the second end. Of course, the side surface of the first functional layer and the side surface of the second functional layer can also correspond to the ends (the first end and the second end) of the display assembly. Since the second support area 200 of the second functional layer does not have a hollow structure (penetrating), the structural stability of the second functional layer can be improved. When the side surface of the second functional layer is subjected to collision, the reliability of the second functional layer with resistance to the collision can be also enhanced. The support effect on the display assembly can be improved, and the negative impact on the display assembly can be reduced.

The second functional layer can include a first support layer 1 and a second support layer 2. A hollow structure can be provided at the member of the first support layer 1 at the second support area 200 penetrating the thickness direction of the second support area 200.

In some embodiments, the surface facing away from the second support layer 2 of the member of the first support layer 1 at the second support area 200 can be one of the third surface and the fourth surface. The surface of the second support layer 2 facing away from the first support layer 1 can be the other one of the third surface and the fourth surface. To ensure that the third surface and the fourth surface are relatively independent of each other, the second support area 200 may not include a structure penetrating the third surface and the fourth surface. The member of the second support layer 2 corresponding to the hollow structure of the first support layer 1 can at least be a solid structure to prevent the first support layer 1 and the second support layer 2 from forming a structure penetrating the third surface and the fourth surface after the first support layer 1 overlaps the second support layer 2.

The first support area 100 of the second functional layer can include at least two sub-areas independent of each other. Different sub-areas can have different thicknesses. With different sub-areas with different thicknesses, a partial thickness of the first support area 100 can be reduced while the first support area 100 of the second functional layer satisfies the support effect. Thus, the material amount for the first support area 100 of the second functional layer can be reduced to reduce the weight.

The first surface and the second surface of the first support area 100 can be two opposite surfaces of the sub-area with the largest thickness of the at least two sub-areas. Therefore, with the sub-area having a smaller thickness (smaller than the thickness of the sub-area with the largest thickness), the material amount of the first support area 100 of the second functional layer can be reduced to reduce the weight.

In some embodiments, the first support area 100 of the second functional layer can include a groove structure 101 that does not penetrate the first support area 100 along the thickness direction. The groove structure can be used as one sub-area, while the area of the first support area 100 of the second functional layer without the groove structure can be used as another sub-area. Since the groove structure is recessed along the thickness direction, the thicknesses of the two sub-areas can be different.

As shown in FIG. 1, in some embodiments, the groove structure 101 can be a blind hole. A plurality of groove structures 101 are provided and arranged in a matrix. Thus, the support strength of the first support area 100 of the second functional layer can be ensured while the weight of the first support area 100 of the second functional layer is ensured to be reduced.

That is, the first surface and the second surface can be independent of each other. The first support area 100 may not include a structure penetrating the first surface and the second surface.

The groove structure 101 can be a circular groove to avoid stress concentration. Of course, the groove structure 101 can also be set as a square groove or a through-slot structure that penetrates through two edges of the first support area 100.

In some embodiments, the area of the first support layer 1 at the first support area 100 may not include a hollow structure, while the area of the second support layer 2 at the first support area 100 can include a hollow structure penetrating the second support layer 2 along the thickness direction. Therefore, when the first support layer 1 and the second support layer 2 are stacked, an end of the hollow structure of the area of the second support layer 2 at the first support area 100 can be closed by the area of the first support layer 1 at the first support area 100 (without a hollow structure). Thus, the first support area 100 of the second functional layer may not have a structure penetrating the second functional layer along the thickness direction.

In some other embodiments, the member of the first support layer 1 at the first support area 100 can include a hollow structure penetrating the first support layer 1 along the thickness direction. The member of the second support layer 2 at the first support area 100 may not include the hollow structure. Similarly, when the first support layer 1 and the second support layer 2 are stacked, an end of the hollow structure of the member of the first support layer 1 at the first support area 100 can be closed by the member of the second support layer 2 at the first support area 100 (without a hollow structure). Thus, the first support area 100 of the second functional layer may not include a structure penetrating the first support area 100 along the thickness direction.

The second support layer 2 can include a hollow structure. The hollow structure of the second support layer 2 and the hollow structure of the first support layer 1 can be staggered.

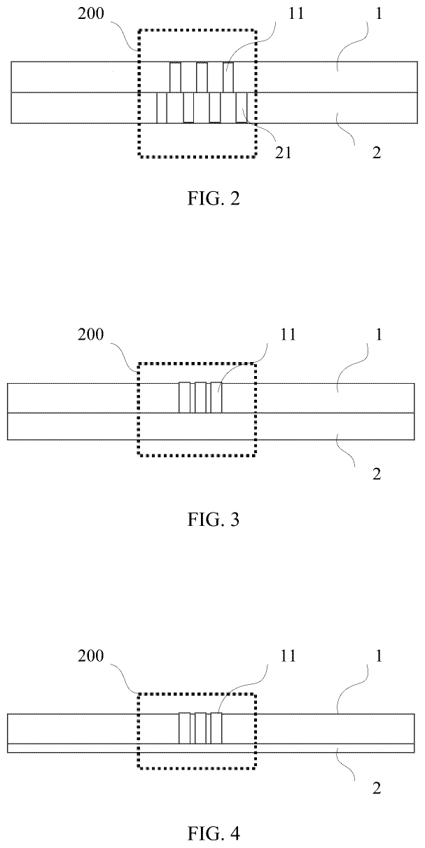

As shown in FIG. 2, in some embodiments, the hollow structure of the first support layer 1 is a first hollow structure 11, and the hollow structure of the second support layer 2 is a second hollow structure 21. The first support layer 1 and the second support layer 2 are stacked, and the first hollow structure 11 and the second hollow structure 21 are staggered. That is, the two ends of the first hollow structure 11 can be two openings on the surfaces of the first support layer 1. One opening (the upward-facing opening in FIG. 2) faces away from the second support layer 2, and the other opening (the downward-facing opening in FIG. 2) is closed by the solid structure of the second support layer 2 (the other member of the second support layer 2 excluding the hollow structure). Thus, the first hollow structure 11 cannot penetrate the second functional layer in the thickness direction. Similarly, the two ends of the second hollow structure 21 are two openings on the surfaces of the second support layer 2. One opening (the downward-facing opening in FIG. 2) faces away from the first support layer 1, and the other opening (the upward-facing opening in FIG. 2) is closed by the solid structure of the first support layer 1 (the member of the first support layer 1 excluding the hollow structure). Thus, the second hollow structure 21 cannot penetrate the second functional layer in the thickness direction.

Furthermore, the first hollow structure 11 can be arranged at the member of the first support layer 1 at the second support area 200, and the second hollow structure 21 can be arranged at the member of the second support layer 2 at the second support area 200. Therefore, the second support area 200 of the second functional layer can include the first hollow structure 11 and the second hollow structure 21 that are staggered. Thus, the second support area 200 of the second functional layer can provide support to the bendable area of the first functional layer, and the second support area 200 of the second functional layer can bend to match the bending operation of the bendable area. Moreover, since the first hollow structure 11 and the second hollow structure 21 are staggered, the external foreign objects cannot penetrate the second functional layer to contact the first functional layer.

Additionally, since the first hollow structure 11 and the second hollow structure 21 are staggered, the structural stability of the second support area 200 of the second functional layer can be ensured to further ensure the support strength of the second support area. When the side surface of the second functional layer is subjected to collision, the reliability for resistance to the collision of the second support area 200 of the second functional layer can be improved.

As shown in FIG. 3, in some embodiments, the hollow structure of the first support layer 1 is the first hollow structure 11, and the second support layer 2 does not include a hollow structure. That is, the two ends of the first hollow structure 11 are two openings on the surfaces of the first support layer 1. One opening (the upward-facing opening in FIG. 2) faces away from the second support layer 2, and the other opening (the downward-facing opening in FIG. 2) is closed by the second support layer 2. Thus, the first hollow structure 11 cannot penetrate the second functional layer in the thickness direction.

Furthermore, the first hollow structure 11 is arranged at the member of the first support layer 1 at the second support area 200. Therefore, the second support area 200 of the second functional layer includes the first hollow structure 11. Thus, the second support area 200 of the second functional layer can provide support to the bendable area of the first functional layer, while the second support area 200 of the second functional layer can bend to match the bending operation of the bendable area. Moreover, since the other opening of the first hollow structure 11 is closed by the second support layer 2, external foreign objects cannot pass through the second functional layer to contact the first functional layer.

Additionally, since the first hollow structure 11 cannot penetrate the second support area 200 of the second functional layer, the structural stability of the second support area 200 of the second functional layer can be ensured to further ensure the support strength of the second support area 200. When the side surface of the second functional layer is subjected to collision, the reliability of resistance to the collision can be improved for the second support area 200 of the second functional layer.

The thickness of the second support layer 2 can be the same or different from the thickness of the first support layer 1.

As shown in FIG. 4, in some embodiments, the hollow structure of the first support layer 1 is the first hollow structure 11. The first hollow structure 11 is arranged at the member of the first support layer 1 at the second support area 200. The second support layer 2 does not include a hollow structure. The thickness of the second support layer 2 is smaller than the thickness of the first support layer 1. Thus, the first hollow structure 11 cannot penetrate the second functional layer in the thickness direction. Since the thickness of the second support layer 2 is smaller than the thickness of the first support layer 1, the bending deformation of the second support area 200 can be facilitated to match the bending operation of the bendable area.

Of course, the thickness of the second support layer 2 can be the same as or different from the thickness of the first support layer 1.

The hollow structure of the first support layer 1 can only be arranged at the member of the first support layer 1 at the second support area 200. The groove that does not penetrate the first support layer 1 in the thickness direction can be arranged at the member of the first support layer 1 at the first support area 100.

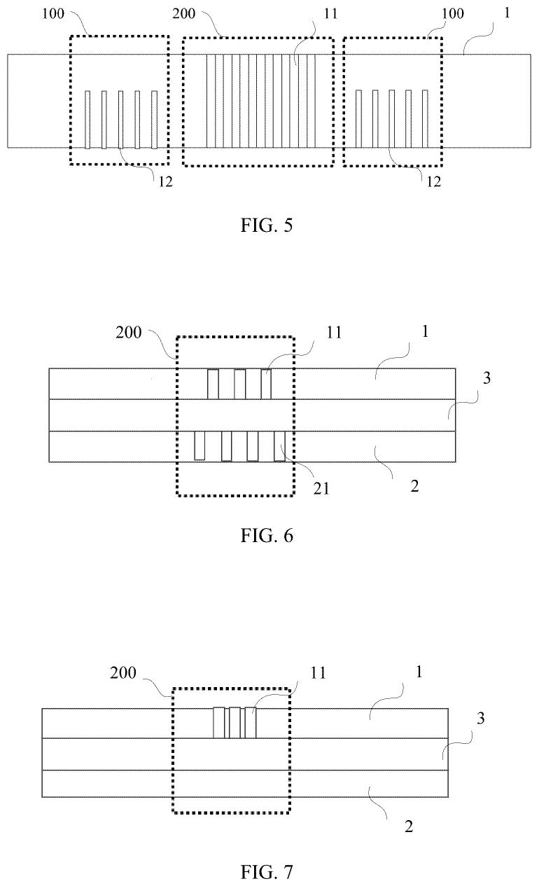

As shown in FIG. 5, in some embodiments, the hollow structure of the first support layer 1 includes the first hollow structure 11 and a first groove structure 12. The first hollow structure 11 is arranged at the member of the first support layer 1 at the second support area 200. The first groove structure 12 is arranged at the member of the first support layer 1 at the first support area 100. The first groove structure 12 does not penetrate the first support layer 1 in the thickness direction. Thus, the bending ability of the member of the first support layer 1 at the second support area 200 can be better than the bending ability of the member of the first support layer 1 at the first support area 100. The support strength of the member of the first support layer 1 at the first support area 100 can be better than the support strength of the member of the first support layer 1 at the second support area 200.

The first hollow structure 11 and the first groove structure 12 can be etching patterns. The first hollow structure 11 can be a whole etching pattern, which penetrates the first support layer 1. The first groove structure 12 can be a half etching pattern, which does not penetrate the first support layer 1.

The second support layer 2 can include structures corresponding to the first hollow structure 11 and the first groove structure 12. The member of the second support layer 2 corresponding to the first hollow structure 11 can be a solid structure. The member of the second support layer 2 corresponding to the first groove structure can be a solid structure or a hollow structure.

As shown in FIG. 6, in some embodiments, the hollow structure of the first support layer 1 includes a first hollow structure 11, and the hollow structure of the second support layer 2 includes a second hollow structure 21. The first support layer 1 and the second support layer 2 can be connected through a pressure-sensitive material 3 to allow the pressure-sensitive material 3 to be between the first support layer 1 and the second support layer 2. The pressure-sensitive material 3 can cover the first support layer 1 and the second support layer 2. In some other embodiments, the member of the pressure-sensitive material 3 corresponding to the first hollow structure 11 and/or the second hollow structure 21 can be hollow. The pressure-sensitive material 3 can be a connection material. The thickness of the pressure-sensitive material can be very thin, as long as the pressure-sensitive material 3 satisfies the connection needs between the first support layer 1 and the second support layer 2.

In some embodiments, the pressure-sensitive material 3 can be a pressure-sensitive adhesive (PSA). In some other embodiments, another material can be selected to connect the first support layer 1 and the second support layer 2, or another member can be configured to apply pressure to cause the first support layer 1 and the second support layer 2 to approach each other. Thus, the first support layer 1 and the second support layer 2 can be stacked to form a stable structure without a connection material, which is not listed here and is in the scope of the present disclosure.

As shown in FIG. 7, in some embodiments, the hollow structure of the first support layer 1 is a first hollow structure 11. The first hollow structure 11 is arranged at the member of the first support layer 1 at the second support area 200. The second support layer 2 does not include a hollow structure. The first support layer 1 and the second support layer 2 can be connected through a pressure-sensitive material 3 to cause the pressure-sensitive material 3 to be arranged between the first support layer 1 and the second support layer 2. The pressure-sensitive material 3 can cover the first support layer 1 and the second support layer 2, or the member of the pressure-sensitive material 3 corresponding to the first hollow structure 11 can be hollow. The pressure-sensitive material 3 can be a connection material. The thickness can be very thin, as long as the connection requirement of the first support layer 1 and the second support layer 2 is satisfied.

In some other embodiments, the whole second support area 200 may not include a hollow structure. The thickness of the second support area 200 can be smaller than the thickness of the first support area 100. That is, the distance between the third surface and the fourth surface can be smaller than the distance between the first surface and the second surface. Thus, the second support area 200 does not include a structure penetrating the third surface and the fourth surface, and the amount of solid material per unit area between the third surface and the fourth surface is smaller than the amount of solid material per unit area between the first surface and the second surface to facilitate the bending deformation of the second support area 200 to match the bending operation of the bendable area.

The second functional layer of embodiments of the present disclosure can include the first support layer 1 and the second support layer 2, or the second functional layer can have a single-layer structure.

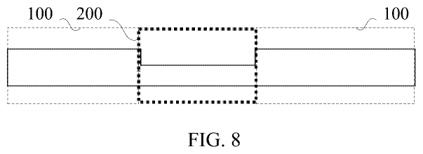

As shown in FIG. 8, in some embodiments, the second support area 200 of the second functional layer sinks relative to the first support area 100. That is, one surface of the second functional layer (the surface shown in FIG. 7) includes a groove not penetrating the second functional layer along the thickness direction. The groove is the second support area 200.

Of course, the grooves not penetrating the second functional layer in the thickness direction can be provided on two surfaces of the second functional layer (the surface shown in FIG. 7 and the downward-facing surface).

The second functional layer of embodiments of the present disclosure can further include at least a third support layer. That is, besides the first support layer 1 and the second support layer 2, the second functional layer can at least include the third support layer, which is not described in detail here and is also in the scope of the present disclosure.

The present disclosure further provides an electronic device, including a body and a display assembly.

The body can be bendable. The display assembly can include a first functional layer and a second functional layer.

The first functional layer can be arranged on a side of the second functional layer facing away from the body. That is, the first functional layer, the second functional layer, and the body can be arranged in sequence. The body and the display assembly can be in a connection state, or the body and the display assembly can be grouped opposite to each other to be in a cooperation state through another member.

The first functional layer can be configured for display and include a bendable area. To facilitate the display surface of the first functional layer to be exposed to the outside, the display surface of the first functional layer can face away from the second functional layer. The display surface of the first functional layer can be a surface outputting the display information (e.g., light).

The second functional layer can be connected to the body and configured to provide support to the first functional layer.

The second functional layer can include a first support area 100 and a second support area 200. The second support area 200 can correspond to the bendable area. The first support area 100 can include a first surface and a second surface opposite to each other. The first surface can be close to the first functional layer. The second support area 200 can include a third surface and a fourth surface opposite to each other. The third surface can be close to the first functional layer. The third surface and the fourth surface can be independent of each other. The second support area 200 does not include a structure penetrating the third surface and the fourth surface. Under the unit area, the amount of solid material between the third surface and the fourth surface can be smaller than the amount of solid material between the first surface and the second surface. Moreover, the bendable area of the first functional layer can correspond to the bendable area of the body. That is, the second support area 200 of the second functional layer can correspond to the bendable area of the body.

Since the display assembly includes the above technical effect, the electronic device of the present disclosure can also have the same technical effect.

Further, the electronic device of the present disclosure can also be a foldable device or a rollable device.

By taking the electronic device as a foldable device for example, the body of the electronic device can include a first body and a second body. The first body can rotate relative to the second body. That is, the rotatable connection structure between the first body and the second body can be the bendable area of the body. The bendable area of the display assembly can be arranged between the first body and the second body to cause the bendable area of the display assembly to correspond to the bendable area of the body.

The display assembly can be arranged on a surface of the body that can bend and close. That is, when the body is in a bent and closed state, the first surface of the first body can face the second surface of the second body. When the body is unfolded, the first surface of the first body and the second surface of the second body can have the same orientation.

The first surface of the first body and the second surface of the second body can face the display assembly.

The display assembly can include the first area and the second area. The bendable area of the display assembly can be arranged between the first area and the second area. The first area can correspond to the first body (connected or relatively positioned). The second area can correspond to the second body (connected or relatively positioned).

When the electronic device is in the bent state, the first body and the second body can be folded and closed through the rotatable connection structure. The first surface of the first body can face the second surface of the second body. The display assembly can bend through the bendable area of the display assembly and can be arranged between the first body and the second body.

Since the first functional layer of the display assembly is arranged on the side of the second functional layer of the display assembly facing away from the body, one surface of the second functional layer can face the first surface of the first body and the second surface of the second body. The other surface of the second functional layer can face the first functional layer.

Embodiments of the present disclosure are described in a progressive manner. Each embodiment focuses on the difference from other embodiments. The same or similar parts between the embodiments can be referred to each other.

The above description of embodiments of the present disclosure can enable those skilled in the art to implement or use the present disclosure. Various modifications to embodiments of the present disclosure are obvious to those skilled in the art, and the general principles defined here can be implemented in other embodiments without departing from the spirit or scope of the present disclosure. Therefore, the present disclosure is not be limited to embodiments shown here but conforms to the widest scope consistent with the principles and novel features of the present disclosure.

What is claimed is:

1. A display assembly comprising:
a first functional layer configured for display and including a bendable area; and
a second functional layer configured to provide support to the first functional layer;
wherein:
the second functional layer includes a first support area and a second support area, and the second support area corresponds to the bendable area;
the first support area includes a first surface and a second surface opposite to each other, with the first surface close to the first functional layer, and the second support area includes a third surface and a fourth surface opposite to each other, with the third surface close to the first functional layer;
the third surface and the fourth surface are independent from each other, and the second support area does not have a structure penetrating the third surface and the fourth surface; and
under a unit area, an amount of solid material between the third surface and the fourth surface is less than an amount of solid material between the first surface and the second surface.

2. The display assembly according to claim 1, wherein the second functional layer includes a first support layer and a second support layer, and a member of the first support layer at the second support area includes a hollow structure penetrating a thickness direction of the first support layer.

3. The display assembly according to claim 2, wherein a surface of the member of the first support layer at the second support area facing away from the second support layer is the fourth surface, and a surface of the second support layer faces away from the first support layer is the third surface.

4. The display assembly according to claim 2, wherein the first support area of the second functional layer includes at least two sub-areas independent from each other, and different sub-areas have different thicknesses.

5. The display assembly according to claim 4, wherein the first support area of the second functional layer includes a groove structure that does not penetrate a thickness direction of the first support area.

6. The display assembly according to claim 4, wherein:
a member of the first support layer at the first support area does not include a hollow structure, and a member of the second support layer at the first support area includes a hollow structure penetrating a thickness direction of the second support layer; or
the member of the first support layer at the first support area includes a hollow structure penetrating the thickness direction of the first support layer, and the member of the second support layer at the first support area does not include a hollow structure.

7. The display assembly according to claim 2, wherein the second support layer includes the hollow structure, and the hollow structure of the second support layer and the hollow structure of the first support layer are staggered.

8. The display assembly according to claim 2, wherein a thickness of the second support layer is less than a thickness of the first support layer.

9. The display assembly according to claim 2, wherein the first support layer and the second support layer are connected through a pressure-sensitive material.

10. An electronic device comprising:
a bendable body; and
a display assembly including:
a first functional layer configured for display and including a bendable area; and
a second functional layer connected to the body and configured to provide support to the first functional layer;
wherein:
the second functional layer includes a first support area and a second support area, and the second support area corresponds to the bendable area;
the first support area includes a first surface and a second surface opposite to each other, with the first surface close to the first functional layer, and the second support area includes a third surface and a fourth surface opposite to each other, with the third surface close to the first functional layer;
the third surface and the fourth surface are independent from each other, and the second support area does not have a structure penetrating the third surface and the fourth surface;
under a unit area, an amount of solid material between the third surface and the fourth surface is less than an amount of solid material between the first surface and the second surface; and
the bendable area of the first functional layer corresponds to the bendable area of the body.

11. The electronic device according to claim 10, wherein the body includes:
a first body and a second body, the first body rotating relative to the second body, and the bendable area of the display assembly being arranged between the first body and the second body.

12. The electronic device according to claim 9, wherein the second functional layer includes a first support layer and a second support layer, and a member of the first support layer at the second support area includes a hollow structure penetrating a thickness direction of the first support layer.

13. The electronic device according to claim 12, wherein a surface of the member of the first support layer at the second support area facing away from the second support layer is the fourth surface, and a surface of the second support layer faces away from the first support layer is the third surface.

14. The electronic device according to claim 12, wherein the first support area of the second functional layer includes at least two sub-areas independent from each other, and different sub-areas have different thicknesses.

15. The electronic device according to claim 14, wherein the first support area of the second functional layer includes a groove structure that does not penetrate a thickness direction of the first support area.

16. The electronic device according to claim 15, wherein:
a member of the first support layer at the first support area does not include a hollow structure, and a member of the second support layer at the first support area includes a hollow structure penetrating a thickness direction of the second support layer; or
the member of the first support layer at the first support area includes a hollow structure penetrating the thickness direction of the first support layer, and the member of the second support layer at the first support area does not include a hollow structure.

17. The electronic device according to claim 12, wherein the second support layer includes the hollow structure, and the hollow structure of the second support layer and the hollow structure of the first support layer are staggered.

18. The electronic device according to claim 14, wherein a thickness of the second support layer is less than a thickness of the first support layer.

19. The electronic device according to claim 14, wherein the first support layer and the second support layer are connected through a pressure-sensitive material.
